(19) United States
(12) Patent Application Publication
(10) Pub. No.: US 2026/0181795 A1
(43) Pub. Date: Jun. 25, 2026

(54) DISPLAY DEVICE AND MOVABLE SPEAKER MODULE THEREOF

(71) Applicant: Qisda Corporation, Taoyuan City (TW)

(72) Inventors: Yung-Chun SU, Taoyuan City (TW); Hui-Chieh HU, Taoyuan City (TW)

(73) Assignee: Qisda Corporation, Taoyuan City (TW)

(21) Appl. No.: 19/404,095

(22) Filed: Dec. 1, 2025

(30) Foreign Application Priority Data
Dec. 24, 2024 (CN) 202411909977.5

(51) Int. Cl. H05K 5/02; G06F 1/16; H04R 1/02

(52) U.S. Cl. CPC H05K 5/0204; G06F 1/1605; G06F 1/1656; H04R 1/028; H04R 2499/15

(57) ABSTRACT

A display device is provided. The display device includes a display and a movable speaker module. The display has a housing, a back cover, and a storage space between the housing and the back cover. The movable speaker module is disposed in the storage space and includes a support base and a speaker. The support base is disposed on the back cover and includes at least one slide groove. The support base is movable relative to the display about a first axis extending along the slide groove. The speaker is pivotally mounted on the support base and rotates relative to the support base about a second axis as a rotation center. The first axis is disposed perpendicular to or parallel to the second axis.

This application claims the benefit of People's Republic of China application Serial No. 202411909977.5, filed Dec. 24, 2024, the subject matter of which is incorporated herein by reference.

### BACKGROUND OF THE INVENTION

### Field of the Invention

The invention relates in general to a display device, and more particularly to a display device with a movable speaker module.

### Description of the Related Art

In daily life, monitors can be used with built-in speakers or external speaker modules to play videos and audio, achieving high-quality audio and video effects. Current monitors with built-in speakers often have a sound output area around the monitor to ensure the sound quality of the speakers. However, with such designs, the sound output is directed toward the top, bottom, or left and right sides of the monitor, and the orientation of the speaker cannot be adjusted to produce sound for the user. Consequently, the user cannot experience high-quality stereo sound effects, and further improvements are needed.

### SUMMARY OF THE INVENTION

The invention is directed to a display device and a movable speaker module thereof for improving sound quality and changing sound output direction of the speaker.

According to one aspect of the present invention, a display device is provided. The display device includes a display and a movable speaker module. The display has a housing, a back cover, and a storage space between the housing and the back cover. The movable speaker module is disposed in the storage space and includes a support base and a speaker. The support base is disposed on the back cover and includes at least one slide groove. The support base is movable relative to the display with a first axis extending along the slide groove. The speaker is pivotally mounted on the support base and rotates relative to the support base about a second axis as a rotation center. The first axis is disposed perpendicular to or parallel to the second axis.

According to one aspect of the present invention, a movable speaker module disposed in a storage space of an electronic device is provided. The movable speaker module includes a support base and a speaker. The support base includes at least one slide groove. The support base is movable relative to the display with a first axis extending along the slide groove. The speaker is pivotally mounted on the support base and rotates relative to the support base about a second axis as a rotation center. The first axis is disposed perpendicular to or parallel to the second axis.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a perspective view of a display device and a movable speaker module thereof according to one embodiment of the present invention.

FIG. 2A illustrates the movable speaker module of FIG. 1 in a hidden position.

FIG. 2B illustrates the movable speaker module of FIG. 1 in an open position facing a first orientation.

FIG. 2C illustrates the movable speaker module of FIG. 1 in an open position facing a second orientation.

FIGS. 3A and 3B illustrate a second drive module driving the movable speaker module to rotate.

FIG. 4 illustrates a perspective view of a display device and a movable speaker module thereof according to another embodiment of the present invention.

FIG. 5A illustrates the movable speaker module of FIG. 4 in a hidden position.

FIG. 5B illustrates the movable speaker module of FIG. 4 in an open position facing a first orientation.

FIG. 5C illustrates the movable speaker module of FIG. 4 in an open position facing a second orientation and a third orientation.

FIGS. 6 and 7 illustrate the interchangeable positions of the latching element and the locking element.

### DETAILED DESCRIPTION OF THE INVENTION

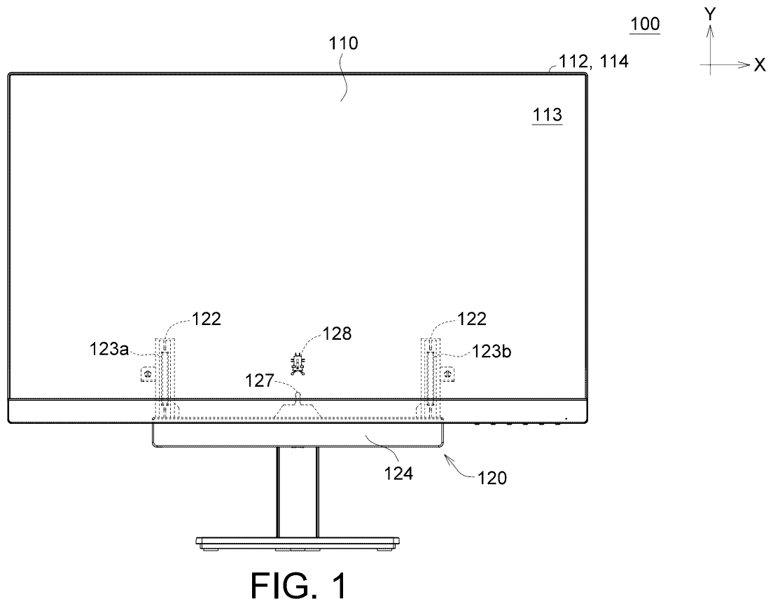

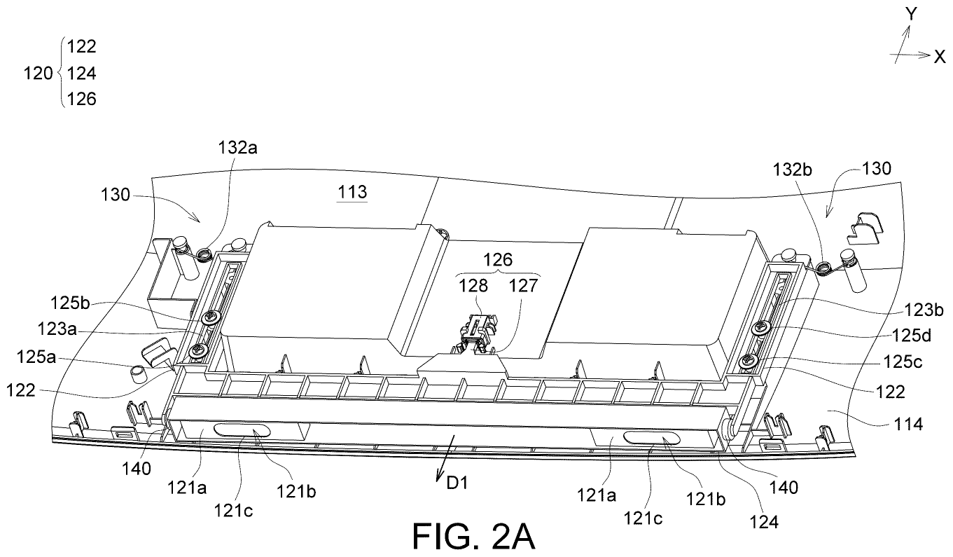

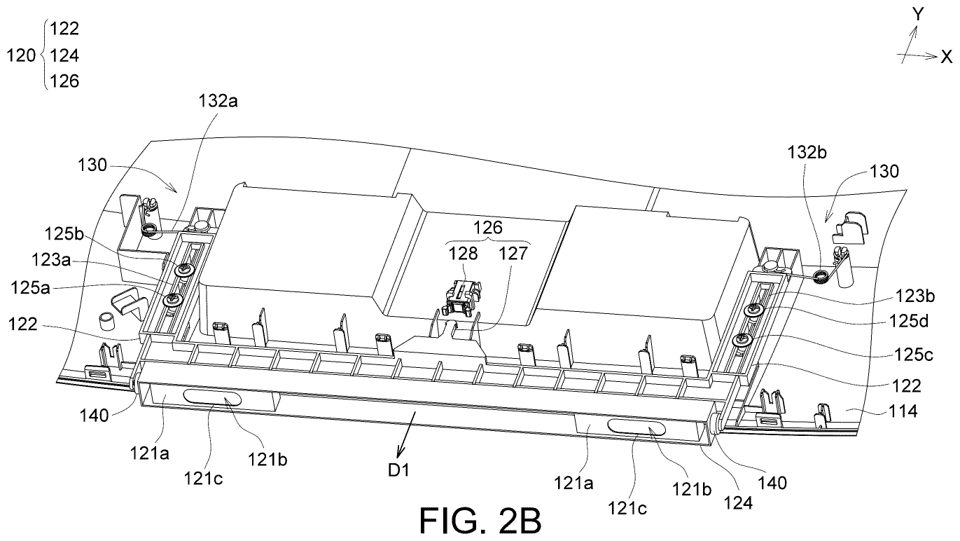

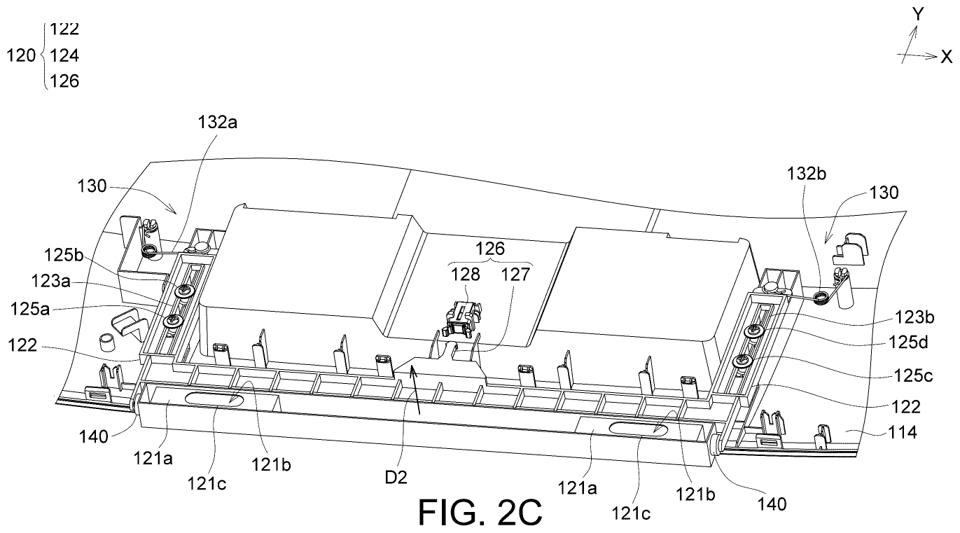

Referring to FIGS. 1 to 2C, FIG. 1 illustrates a perspective view of a display device 100 and a movable speaker module 120 thereof according to one embodiment of the present invention. FIG. 2A illustrates the movable speaker module 120 of FIG. 1 in a hidden position. FIG. 2B illustrates the movable speaker module 120 of FIG. 1 in an open position facing a first orientation D1. FIG. 2C illustrates the movable speaker module 120 of FIG. 1 in an open position facing a second orientation D2.

Referring to FIG. 1, in one embodiment, the display device 100 includes a display 110 and a movable speaker module 120. The movable speaker module 120 can be disposed in a storage space inside the display 110 to form a multimedia playback device having the movable speaker module 120. In this embodiment, a desktop display 110 is used as an example. However, the display device 100 can also be used in mobile devices, such as tablet computers, notebook computers, and other multimedia playback devices, and the present invention is not limited thereto.

As shown in FIG. 1, the display 110 has a housing 112, a back cover 114, and a storage space 113 located between the housing 112 and the back cover 114. The movable speaker module 120 is disposed on the back cover 114 of the display 110 and is movable between a hidden position and an open position. As shown in FIG. 2A, the movable speaker module 120 is located in the hidden position, that is, in the storage space 113 inside the display 110. As shown in FIG. 2B and FIG. 2C, when the movable speaker module 120 is to be used, the movable speaker module 120 can be moved from inside of the display 110 (hidden position) to outside of the display 110 (open position) so that the movable speaker module 120 is exposed outside the display 110. Furthermore, the user can adjust the sound output direction of the movable speaker module 120 according to needs or system internal settings, so that the speaker 124 can output sound directly toward the user or in different sound output directions to achieve high-quality stereo sound effects.

As shown in FIG. 2B, when the movable speaker module 120 is in the open position, the speaker 124 is oriented toward a first orientation D1 (e.g., downward) so that sound can be emitted toward the bottom of the display 110. As shown in FIG. 2C, the movable speaker module 120 can be rotated from the first orientation D1 (e.g., downward) to a second orientation D2 (e.g., toward the front of the display 110) so that sound can be emitted toward the front of the display 110.

In one embodiment, the movable speaker module 120 includes a support base 122, a speaker 124, a plurality of positioning members 125a-125d, and a fastening structure 126. The support base 122 is disposed on the back cover 114. The support base 122 may include, but is not limited to, a first slide groove 123a and a second slide groove 123b arranged in parallel. The first slide groove 123a is located on one side (e.g., the left side) of the support base 122, while the second slide groove 123b is located on the other side (e.g., the right side) of the support base 122. Positioning members 125a-125d are disposed on the back cover 114 and positioned in the corresponding slide grooves. For example, the first and second positioning members 125a, 125b are disposed in the first slide groove 123a and are separated by a predetermined distance, while the third and fourth positioning members 125c, 125d are disposed in the second slide groove 123b and are separated by a predetermined distance. As shown in FIG. 2A, when the movable speaker module 120 moves to the hidden position, the first positioning member 125a and the third positioning member 125c are located at the bottom dead center of the first slide groove 123a and the bottom dead center of the second slide groove 123b, respectively. As shown in FIG. 2B, when the movable speaker module 120 moves to the open position, the second positioning member 125b and the fourth positioning member 125d move toward the top dead center of the first slide groove 123a and the top dead center of the second slide groove 123b, respectively, so that the movable speaker module 120 is positioned outside the display 110.

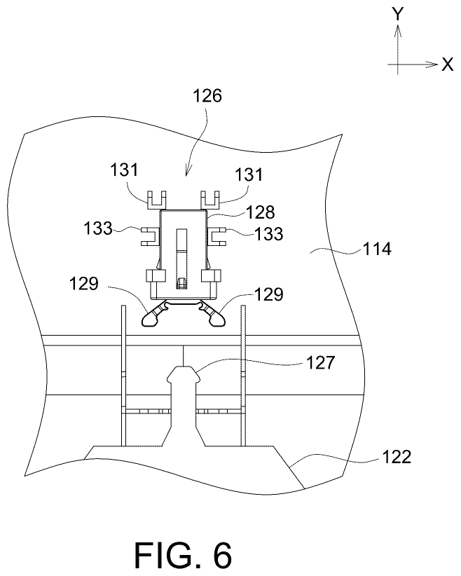

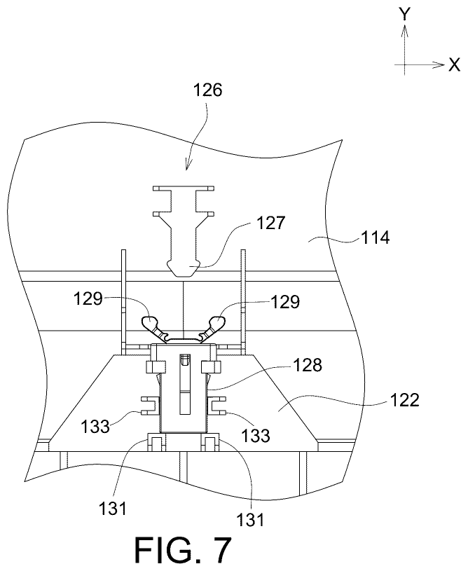

In addition, the support base 122 is movable relative to the display 110 with the extension direction of the slide groove as a first axis (Y axis), for example, linearly moving along the first axis (Y axis). The first axis may include, but is not limited to, a vertical line or a horizontal line, as long as it enables the movable speaker module 120 to move along the slide groove. For a detailed description of the fastening structure 126, please refer to FIG. 6 and FIG. 7, which will be described later.

Referring to FIGS. 2A and 2B, the movable speaker module 120 may include a first drive module 130 disposed in the storage space 113 inside the display 110. The first drive module 130 is used to drive the support base 122 to move along the first axis (Y-axis) and to move the speaker 124 from the inside of the display 110 to the outside. The first drive module 130 may include, but is not limited to, a spring, a motor, a gear, and a rack assembly. In one embodiment, the first drive module 130 is, for example, a torsion spring 132a-132b or a compression spring disposed on opposite sides or at least one side of the support base 122 and connected to the support base 122. The torsion springs 132a-132b can rotate along their central axis to generate torque to push the support base 122 moving in an actuating direction. When the motor drives the gear to rotate relative to the rack assembly, the torque of the motor can be converted into a linear driving force to propel the support base 122 in an actuating direction.

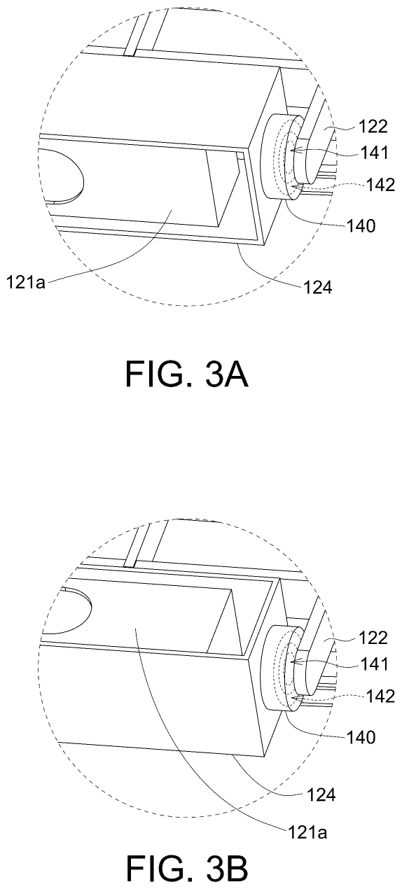

Referring to FIGS. 3A and 3B, schematic diagrams of the second drive module 140 driving the movable speaker module 120 to rotate are illustrated. The movable speaker module 120 may include, but is not limited to, a second drive module 140 disposed on the support base 122. The second drive module 140 is used to drive the speaker 124 to rotate relative to the support base 122. The second drive module 140 may include, but is not limited to, a spring, a motor, a cam assembly, a gear assembly, etc. In one embodiment, the second drive module 140 is, for example, a torsion spring 142, which is located on a pivot 141 (parallel to the second axis) between the support base 122 and the speaker 124. The torsion spring 142 can rotate about the pivot 142 to generate torque, thereby driving the speaker 124 to rotate in a certain direction. If the speaker 124 rotates relative to the support base 122 using a motor to drive the cam assembly or gear assembly, the torque of the motor can be converted into a rotational driving force, thereby driving the speaker 124 to rotate in a certain direction.

That is, the speaker 124 rotates relative to the support base 122 with a second axis (X axis) as the rotation center. The first axis (Y axis) is arranged perpendicularly to the second axis (X axis), as shown in FIG. 1.

As shown in FIG. 2B and FIG. 2C, the speaker 124 includes a sound box 121a and a speaker body 121b arranged in the sound box 121a. The sound box 121a has an opening 121c, which can serve as a sound outlet for the speaker 124. When the speaker 124 is located inside the display 110, the opening 121c of the sound box 121a faces a first orientation D1 (for example, downward); when the speaker 124 is located outside the display 110, the opening 121c of the sound box 121a can be located in the first orientation D1 or rotated from the first orientation D1 to a second orientation D2. The first orientation D1 and the second orientation D2 are different, for example, the first orientation D1 and the second orientation D2 differ by 90 degrees or other suitable angles. The above method can be adjusted according to user needs or system settings.

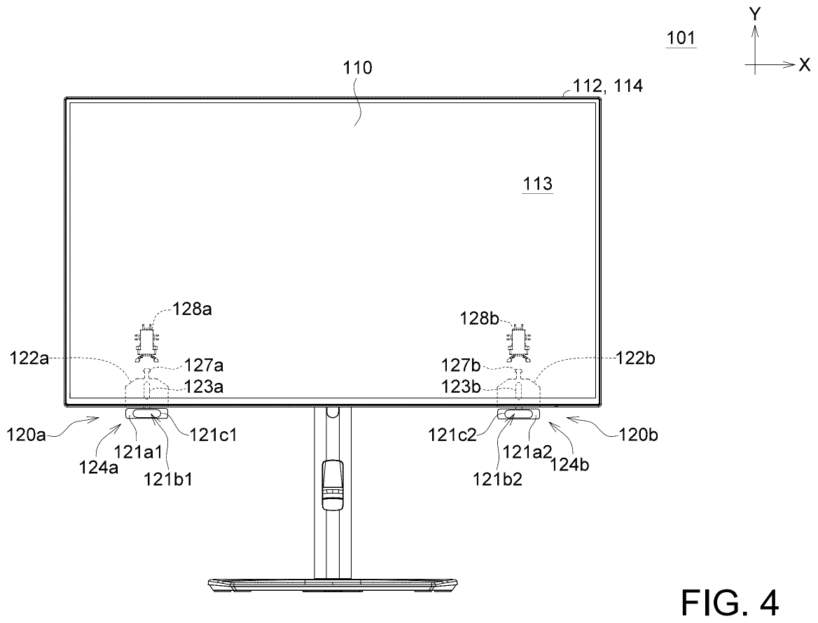

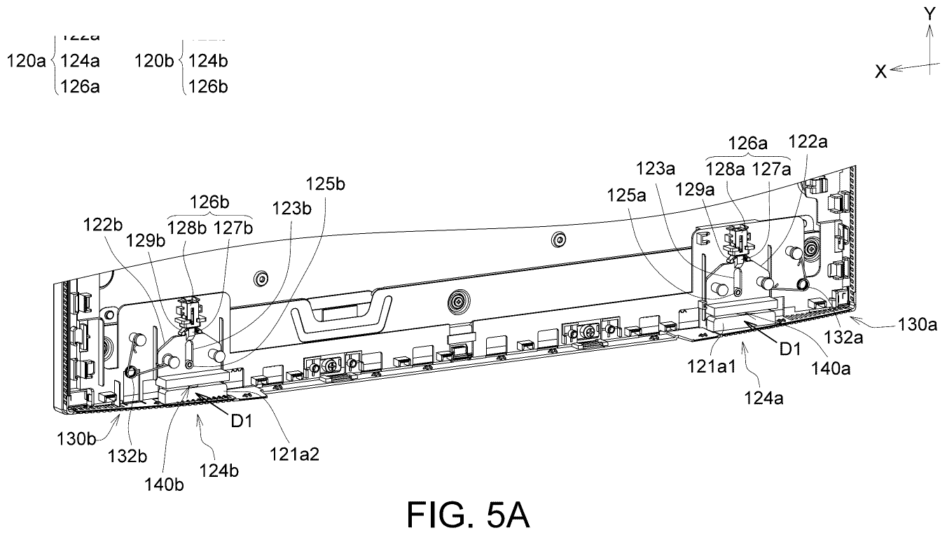

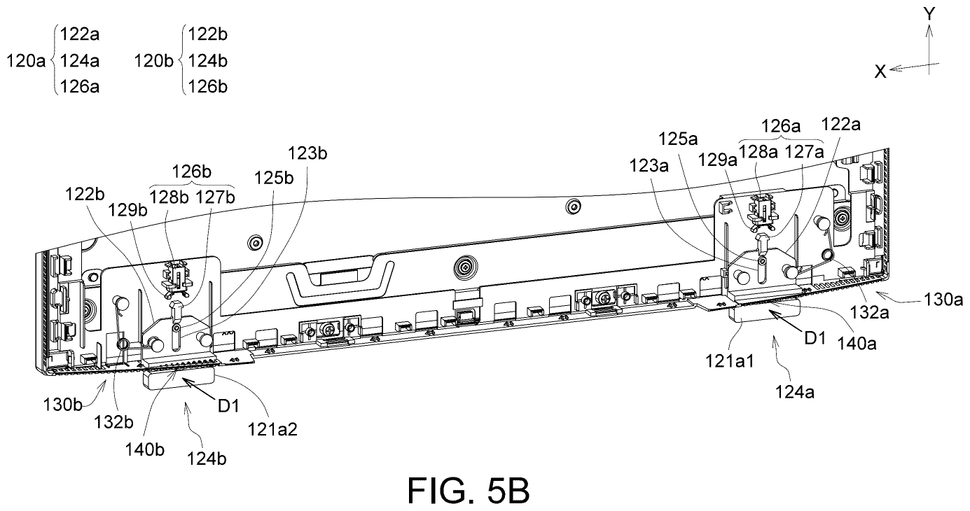

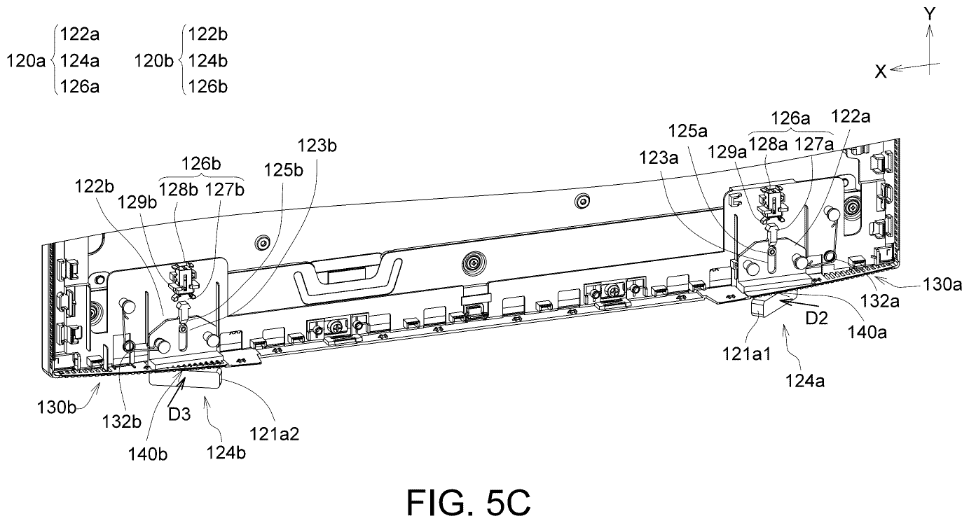

Referring to FIGS. 4 to 5C, FIG. 4 illustrates a perspective view of a display device 101 and a movable speaker module 120 thereof according to another embodiment of the present invention. FIG. 5A illustrates the movable speaker module 120 of FIG. 4 in a hidden position. FIG. 5B illustrates the movable speaker module 120 of FIG. 4 in an open position facing the first orientation D1. FIG. 5C illustrates the movable speaker module 120 of FIG. 4 in an open position facing the second orientation D2 and the third orientation D3, respectively.

Referring to FIG. 4, in one embodiment, the display device 101 includes a display 110 and movable speaker modules 120a-120b. The movable speaker modules 120a-120b can be disposed in a housing space 113 inside the display 110. In this embodiment, a desktop display 110 is used as an example, but the display device 101 can also be used in mobile devices, such as tablet computers, notebook computers, and other multimedia playback devices, and the present invention is not limited thereto.

This embodiment differs from the above embodiments in that the movable speaker modules 120a-120b can include a first speaker 124a, a second speaker 124b, a first bracket 122a, and a second bracket 122b. As shown in FIG. 4, the first speaker 124a and the first bracket 122a are independently disposed on one side (e.g., the left side) of the display 110, while the second speaker 124b and the second bracket 122b are independently disposed on the other side (e.g., the right side) of the display 110. The first speaker 124a is pivotally mounted on the first bracket 122a and rotates relative to the first bracket 122a about a second axis (parallel to the Y axis). Furthermore, the second speaker 124b is pivotally mounted on the second bracket 122b and rotates relative to the second bracket 122b about a second axis (parallel to the Y axis).

As shown in FIG. 4, the display 110 includes a housing 112, a back cover 114, and a storage space 113 located between the housing 112 and the back cover 114. The movable speaker modules 120a and 120b are mounted on the back cover 114 of the display 110 and are movable between a hidden position and an open position. As shown in FIG. 5A, the movable speaker module 120 is located in the hidden position, i.e., within the storage space 113 of the display 110. As shown in FIGS. 5B and 5C, when the movable speaker modules 120a and 120b are used, the first speaker 124a and the second speaker 124b of the movable speaker modules 120a-120b can be moved from inside of the display 110 (hidden position) to outside of the display 110 (open position), respectively, so that the first speaker 124a and the second speaker 124b are exposed outside the display 110. Furthermore, the user can adjust the sound output directions of the first speaker 124a and the second speaker 124b according to needs or system settings, so that the first speaker 124a and the second speaker 124b can output sound toward the user or in different directions, thereby achieving high-quality stereo sound.

As shown in FIG. 5B, when the movable speaker modules 120a and 120b are in the open position, the first speaker 124a and the second speaker 124b are both oriented toward a first orientation D1 (e.g., toward the front of the display 110) so that sound can be emitted toward the front of the display 110. As shown in FIG. 5C, the first speaker 124a of the movable speaker modules 120a-120b can be rotated from the first orientation D1 to a second orientation D2 (e.g., toward the front of the center vertical line of the display 110) so that sound can be emitted toward a user located in front of the display 110. The second speaker 124b can be rotated from the first orientation D1 to a third orientation D3 (e.g., toward the front of the center vertical line of the display 110) so that sound can be emitted toward the user located in front of the display 110. The second orientation D2 and the third orientation D3 can be adjusted according to user needs or system settings and are not limited to fixed directions.

In one embodiment, the movable speaker modules 120a and 120b include a first bracket 122a, a first speaker 124a, a second bracket 122b, a second speaker 124b, a plurality of positioning members 125a and 125c, a first fastening structure 126a, and a second fastening structure 126b. The first bracket 122a is disposed on the back cover 114. The first bracket 122a may include, but is not limited to, a first slot 123a, which may be located in the center of the first bracket 122a. The second bracket 122b may include, but is not limited to, a second slot 123b, which may be located in the center of the second bracket 122b. The positioning members 125a and 125c are disposed on the back cover 114 and are positioned in the corresponding slots. For example, the first positioning member 125a is disposed in the first slot 123a, and the third positioning member 125c is disposed in the second slot 123b. As shown in FIG. 5A, when the movable speaker module 120 moves to the hidden position, the first positioning member 125a and the third positioning member 125c are located at the bottom dead center of the first slide groove 123a and the bottom dead center of the second slide groove 123b, respectively. As shown in FIG. 5B, when the movable speaker module 120 moves to the open position, the first positioning member 125a and the third positioning member 125c are located near the top dead center of the first slide groove 123a and the top dead center of the second slide groove 123b, respectively, so that the movable speaker module 120 is positioned outside the display 110.

In addition, the first bracket 122a and the second bracket 122b are movable relative to the display 110 along a first axis (Y-axis) extending in the direction of the slide groove, for example, linearly moving along the first axis (Y-axis). The first axis may include, but is not limited to, a vertical line or a horizontal line, as long as it enables the movable speaker modules 120a-120b to move along the slide groove.

Referring to FIGS. 5A and 5B, the movable speaker modules 120a and 120b may include first drive modules 130a-130b disposed in the storage space 113 within the display 110. The first drive modules 130a-130b are configured to respectively drive the first bracket 122a and the second bracket 122b to move along the first axis (Y-axis), thereby moving the first speaker 124 and the second speaker 124b from the inside of the display 110 to the outside. The first drive modules 130a and 130b may include, but are not limited to, a spring, a motor, a gear, and a rack assembly. In one embodiment, the first drive modules 130a and 130b are, for example, torsion springs 132a-132b or compression springs, which are disposed on the first bracket 122a and the second bracket 122b, and connected to the first bracket 122a and the second bracket 122b, respectively. The torsion springs 132a-132b can rotate along their central axes to generate torque, thereby respectively pushing the first bracket 122a and the second bracket 122b to move in an actuating direction. When a motor drives the gear to rotate relative to the rack assembly, the torque of the motor can be converted into a linear driving force, thereby respectively pushing the first bracket 122a and the second bracket 122b to move in an actuating direction.

Referring to FIGS. 5A and 5B, schematic diagrams of the second drive modules 140a-140b driving the movable speaker modules 120a-120b to rotate are illustrated. The movable speaker modules 120a-120b may include, but are not limited to, a second drive module 140a-140b, which is respectively disposed on the first bracket 122a and the second bracket 122b. The second drive modules 140a-140b are configured to respectively drive the first speaker 124a to rotate relative to the first bracket 122a and drive the second speaker 124b to rotate relative to the second bracket 122b. The second drive modules 140a-140b may include but are not limited to springs, motors, cam assembly, gear assembly, etc. In one embodiment, the second drive modules 140a-140b are, for example, torsion springs, respectively located on the pivot axis (parallel to the Y-axis) between the first bracket 122a and the first speaker 124a and the pivot axis (parallel to the Y-axis) between the second bracket 122b and the second speaker 124a. The torsion springs can rotate along their pivot axes to generate torque, thereby driving the first speaker 124a and the second speaker 124b to rotate in a certain direction. If the speakers are driven by a motor to drive a cam assembly or a gear assembly relative to the first bracket 122a and the second bracket 122b, the torque of the motor can be converted into a rotational driving force, thereby driving the first speaker 124a and the second speaker 124b to rotate in a certain direction.

In other words, the first speaker 124a rotates relative to the first bracket 122a about a second axis (the Y-axis), and the second speaker 124b rotates relative to the second bracket 122b about a second axis (the Y-axis). The first axis (Y axis) is arranged parallel to the second axis (Y axis), as shown in FIG. 5A.

As shown in FIG. 5B and FIG. 5C, the first speaker 124a may include a first speaker body 121b1 and a first sound box 121a1 . The first speaker body 121b1 is disposed in the first sound box 121a1. The first sound box 121a1 has a first opening 121c1 , which serves as a sound outlet for the first speaker 124 a. When the first speaker 124a is located inside the display 110, the opening 121c1 of the first sound box 121a 1 faces a first orientation D1 (e.g., forward). When the first speaker 124a is located outside the display 110, the opening 121c1 of the first sound box 121a1 may be located in the first orientation D1 or may be directed from the first orientation D1 to a second orientation D2. The first orientation D1 is different from the second orientation D2. For example, the first orientation D1 and the second orientation D2 differ by 10 to 90 degrees or other suitable angles. The above method can be adjusted according to user needs or system settings.

In addition, the second speaker 124b may include a second speaker body 121b2 and a second sound box 121a2 . The second speaker body 121b2 is disposed in the second sound box 121a2. The second sound box 121a2 has a second opening 121c2, which can serve as a sound outlet for the second speaker 124b. When the second speaker 124b is located inside the display 110, the opening 121c1 of the second sound box 121a1 faces a first orientation D1 (e.g., forward). When the second speaker 124b is located outside the display 110, the opening 121c2 of the second sound box 121a2 can be located in the first orientation D1 or directed from the first orientation D1 to a third orientation D3. The first orientation D1 and the third orientation D3 are different, for example, by 10 to 90 degrees or other suitable angles. The above method can be adjusted according to user needs or system settings.

Furthermore, the movable speaker modules 120a and 120b may include a first latching element 127a and a first locking element 128a. The first latching element 127a and the first locking element 128a are interchangeably disposed on the back cover 114 of the display 110 and the first bracket 122a. The first locking element 128a includes a pair of first clamping arms 129a that can be opened and closed. The pair of first clamping arms 129a may be used to clamp or release the first latching element 127a, so that the first speaker 124a is positioned within the display 110 or movable relative to the display 110. Furthermore, the movable speaker modules 120a and 120b may include a second latching element 127b and a second locking element 128b. The second latching element 127b and the second locking element 128b may be interchangeably disposed on the back cover 114 of the display 110 and the second bracket 122b. The second locking element 128b includes a pair of second clamping arms 129b that can be opened and closed. The second clamping arms 129b may be used to clamp or release the second latching element 127b, so that the second speaker 124b is positioned within the display 110 or movable relative to the display 110.

Referring to FIGS. 6 and 7, schematic diagrams of the interchangeable positions of the latching element 127 and the locking element 128 are illustrated. In FIGS. 6 and 7, the fastening structure 126 is used to secure the support base 122 (or bracket) to the back cover 114 (or middle frame) of the display 110. The fastening structure 126 is, for example, a push-to-close latch, including a latching element 127 and a locking element 128. The latching element 127 and the locking element 128 are interchangeably disposed on the back cover 114 of the display 110 and the support base 122. In FIG. 6, the latching element 127 is disposed on the support base 122. The latching element 127 is, for example, a latch or tenon, located on one side of the locking element 128 and extending toward the locking element 128. The locking element 128 includes a pair of retractable clamping arms 129. The clamping arms 129 may be configured to clamp the latching element 127, so that the speaker 124 is secured within the display 110. Furthermore, when the latching element 127 is pressed again, the clamping arms 129 release the latching element 127, so that the speaker 124 movable relative to the display 110.

Referring to FIGS. 6 and 7, the locking element 128 may include a fastening structure 133 for fixing the locking element 128 to the back cover 114 of the display 110 or the support base 122. The fastening structure 133 may include, but is not limited to, two stoppers 131, the stoppers 131 are respectively disposed on the left and right sides of the locking element 128 and not connected to each other. For example, the two stoppers 131 may be disposed at corners of the upper or lower side of the locking element 128, and the two stoppers 131 may not be located in the extending direction of the latching element 127 along the first axis (Y-axis).

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display device, comprising:
a display having a housing, a back cover, and a storage space between the housing and the back cover; and
a movable speaker module disposed in the storage space, the movable speaker module comprising:
a support base disposed on the back cover, the support base comprising at least one slide groove, and the support base being movable relative to the display with a first axis extending along the slide groove; and
a speaker pivotally mounted on the support base, the speaker rotating relative to the support base about a second axis, and the first axis being perpendicular or parallel to the second axis.

2. The display device of claim 1, wherein the movable speaker module further comprises a first drive module disposed in the storage space, the first drive module is configured to drive the support base to move along the first axis, so that the speaker moves from inside of the display to outside.

3. The display device of claim 2, wherein the movable speaker module further comprises a second drive module disposed on the support base, the second drive module is configured to drive the speaker to rotate relative to the support base.

4. The display device of claim 1, wherein the speaker comprises a speaker body and a sound box, the speaker body is disposed within the sound box, and the sound box has an opening; when the speaker is located inside the display or moves to outside of the display, the opening faces a first orientation or directs from the first orientation to a second orientation.

5. The display device of claim 1, wherein the movable speaker module further comprises a latching element and a locking element, the latching element and the locking element are interchangeably disposed on the display and the support base, the locking element comprises a pair of expandable and retractable clamping arms, and the pair of clamping arms is configured to clamp or release the latching element, so that the speaker is positioned within the display or movable relative to the display.

6. The display device of claim 5, wherein the locking element comprises a fastening structure for securing the locking element to the display or the support base, wherein the fastening structure comprises two stoppers, the two stoppers are disposed on opposite sides of the locking element and not located in an extending direction of the latching element along the first axis.

7. The display device of claim 1, wherein the speaker comprises a first speaker and a second speaker, and the support base comprises a first bracket and a second bracket, the first speaker is pivotally mounted on the first bracket, and the second speaker is pivotally mounted on the second bracket, the first speaker rotates relative to the first bracket about the second axis, and the second speaker rotates relative to the second bracket about the second axis.

8. The display device of claim 7, wherein the first speaker comprises a first speaker body and a first sound box, the first speaker body is disposed in the first sound box and the first sound box has a first opening; when the first speaker is moved to outside of the display, the first opening faces a first orientation or directs from the first orientation to a second orientation.

9. The display device of claim 8, wherein the second speaker comprises a second speaker body and a second sound box, the second speaker body is disposed in the second sound box and the second sound box has a second opening; when the second speaker is moved to outside of the display, the second opening faces the first orientation or directs from the first orientation to a third orientation, and the second orientation is different from the third orientation.

10. The display device of claim 7, wherein the movable speaker module further comprises a first latching element and a first locking element, the first latching element and the first locking element are interchangeably mounted on the display and the first bracket, the first locking element comprising a pair of first clamping arms that can be opened and retracted, the pair of first clamping arms is configured to clamp or release the first latching element, so that the first speaker is positioned within the display or movable relative to the display.

11. The display device of claim 10, wherein the movable speaker module further comprises a second latching element and a second locking element, the second latching element and the second locking element are interchangeably mounted on the display and the second bracket, the second locking element comprising a pair of second clamping arms that can be opened and retracted, the pair of second clamping arms is configured to clamp or release the second latching element, so that the second speaker is positioned within the display or movable relative to the display.

12. A movable speaker module disposed in a storage space of an electronic device, the movable speaker module comprising:
a support base, comprising at least one slide groove, the support base being movable relative to the electronic device with a first axis extending along the slide groove; and
a speaker pivotally mounted on the support base, the speaker rotating relative to the support base about a second axis, and the first axis being perpendicular or parallel to the second axis.

13. The movable speaker module of claim 12, further comprises a first drive module disposed in the storage space, the first drive module is configured to drive the support base to move along the first axis, so that the speaker moves from inside of the display to outside.

14. The movable speaker module of claim 13, further comprising a second drive module disposed on the support base, the second drive module being configured to drive the speaker to rotate relative to the support base.

15. The movable speaker module of claim 12, wherein the speaker comprises a speaker body and a sound box, the speaker body is disposed within the sound box, and the sound box has an opening; when the speaker is located inside the electronic device or moves to outside of the electronic device, the opening faces a first orientation or directs from the first orientation to a second orientation.

16. The movable speaker module of claim 12, further comprising a latching element and a locking element, the latching element and the locking element being interchangeably disposed on the electronic device and the support base, the locking element comprising a pair of expandable and retractable clamping arms, and the pair of clamping arms being configured to clamp or release the latching element, so that the speaker is positioned within the electronic device or movable relative to the electronic device.

17. The movable speaker module of claim 16, wherein the locking element comprises a fastening structure for securing the locking element to the electronic device or the support base, wherein the fastening structure comprises two stoppers, the two stoppers are disposed on opposite sides of the locking element and not located in an extending direction of the latching element along the first axis.

18. The movable speaker module of claim 12, wherein the speaker comprises a first speaker and a second speaker, and the support base comprises a first bracket and a second bracket, the first speaker is pivotally mounted on the first bracket, and the second speaker is pivotally mounted on the second bracket, the first speaker rotates relative to the first bracket about the second axis, and the second speaker rotates relative to the second bracket about the second axis.

19. The movable speaker module of claim 18, wherein the first speaker comprises a first speaker body and a first sound box, the first speaker body is disposed in the first sound box and the first sound box has a first opening; when the first speaker is moved to outside of the display, the first opening faces a first orientation or directs from the first orientation to a second orientation.

20. The movable speaker module of claim 19, wherein the second speaker comprises a second speaker body and a second sound box, the second speaker body is disposed in the second sound box and the second sound box has a second opening; when the second speaker is moved to outside of the display, the second opening faces the first orientation or directs from the first orientation to a third orientation, the second orientation is different from the third orientation.
